(19) United States
(12) Patent Application Publication
(10) Pub. No.: US 2023/0097280 A1
(43) Pub. Date: Mar. 30, 2023

(54) MASK BLANK, TRANSFER MASK, AND METHOD FOR MANUFACTURING SEMICONDUCTOR DEVICE

(71) Applicants: HOYA CORPORATION, Tokyo (JP); HOYA ELECTRONICS SINGAPORE PTE. LTD., Singapore (SG)

(72) Inventors: Osamu NOZAWA, Tokyo (JP); Keishi AKIYAMA, Tokyo (JP); Hok Tak Lim, Singapore (SG); Tham Hui Jun, Singapore (SG)

(73) Assignees: HOYA CORPORATION, Tokyo (JP); HOYA ELECTRONICS SINGAPORE PTE. LTD., Singapore (SG)

(21) Appl. No.: 17/801,377

(22) PCT Filed: Mar. 8, 2021
(86) PCT No.: PCT/JP2021/008915

§ 371 Date: Aug. 22, 2022

(30) Foreign Application Priority Data
Mar. 19, 2020 (JP) 2020-049162

(51) Int. Cl. G03F 1/32; G03F 1/24; G03F 1/60; G03F 1/80

(52) U.S. Cl. CPC G03F 1/32; G03F 1/24; G03F 1/60; G03F 1/80

(57) ABSTRACT

An object is to provide a mask blank

A mask blank having a substrate and a thin film, the substrate includes two main surfaces and a side surface with a chamfered surface provided between the two main surfaces and the side surface, one main surface of the two main surfaces includes an inner region including a center of the main surface and an outer peripheral region outside of the inner region, the thin film is provided on the inner region of the main surface, the surface reflectance Rs of the outer peripheral region with respect to light of 400 nm to 700 nm wavelength is 10% or less, and provided that Rf is the surface reflectance with respect to light of 400 nm to 700 nm wavelength in one section among sections of the thin film in the range of 9 nm to 10 nm film thickness, the contrast ratio (Rf/Rs) is 3.0 or more.

### CROSS-REFERENCE TO RELATED APPLICATIONS

This application is the National Stage of International Application No. PCT/JP2021/008915, filed Mar. 8, 2021, which claims priority to Japanese Patent Application No. 2020-049162, filed Mar. 19, 2020, and the contents of which is incorporated by reference.

### TECHNICAL FIELD

The present disclosure relates to a mask blank, a transfer mask manufactured using the mask blank, and a method of manufacturing a semiconductor device using the transfer mask.

### BACKGROUND ART

Generally, in the manufacturing process of a semiconductor device, photolithography is used to form a fine pattern. Multiple substrates called transfer masks are usually utilized in forming the fine pattern. In order to miniaturize the pattern of the semiconductor device, in addition to miniaturization of a mask pattern formed in a transfer mask, it is necessary to shorten the wavelength of an exposure light source used in photolithography. Shortening of wavelengths has been advancing recently from the use of a KrF excimer laser (wavelength 248 nm) to an ArF excimer laser (wavelength 193 nm) as an exposure light source in the manufacture of semiconductor devices.

In recent years, a phase-shift mask referred to as a half tone phase shift mask has been developed as one of these transfer masks. The half tone phase shift mask includes a mask pattern to be formed on a transparent substrate, the mask pattern configured from a portion that transmits light of an intensity that substantially contributes to exposure (light-transmissive portion) and a portion that transmits light of an intensity that substantially does not contribute to exposure (light-semitransmissive portion), and shifts the phase of light passing through the light-semitransmissive portion, so that the phase of the light passed through the light-semitransmissive portion is substantially inverted with respect to the phase of the light transmitted through the light-transmissive portion, such that the lights transmitted near the boundary between the light-transmissive portion and the light-semitransmissive portion cancel each other to thereby maintain good contrast at the boundary.

However, as the wavelength of laser light used for exposure becomes shorter, the energy of the laser light increases, resulting in greater damage to a light-semitransmissive film by exposure. To enhance durability of a light-semitransmissive film against laser light, it is effective to make the light-semitransmissive film denser. On the other hand, however, if the sheet resistance of the light-semitransmissive film becomes large, charge builds up in the light-semitransmissive film causing charge-up during patterning a resist film formed on the light-semitransmissive film by electron beam writing, resulting in the problem of inaccurate pattern writing.

Regarding the above problem, Patent Document 1 discloses a technique for preventing charge-up by forming an exposed portion 5 without a phase shift film 2 at the periphery of a transparent substrate 1, and covering the exposed portion 5 and the phase shift film 2 with a light shielding film consisting of a material having conductivity to an extent of not being charged up when patterning the resist film 4 by an electron beam writing.

### PRIOR ART PUBLICATION

### Patent Document

[Patent Document 1]
Japanese Patent Application Publication 2006-184353

### SUMMARY OF THE DISCLOSURE

### Problems to be Solved by the Disclosure

In the mask blank described above, the light shielding film is formed over a wide area of the substrate, covering a chamfered surface and a side surface. On the other hand, with miniaturization of patterns, further reduction in thickness is being advanced in a light shielding film used also as a hard mask, such as the film thickness of 40 nm or less. Generally, a thin film including a light shielding film of a mask blank is formed on a substrate by sputtering method. When forming a thin film by sputtering method, an incident angle of sputtering particles on a chamfered surface or side surface is more acute than an incident angle of sputtering particles on a main surface of the substrate. Therefore, the thickness of a thin film formed on a chamfered surface and a side surface is much thinner than the thickness of a thin film formed on a main surfaces. In addition, adhesion strength of a thin film formed on a chamfered surface and a side surface is weaker than that of a thin film formed on a main surface. Due to these circumstances, there was a problem that a light shielding film on portions formed on a chamfered surface and a side surface of a substrate tends to peel off, and the light shielding film on these portions tends to peel off and generate dust during handling of a mask blank. To solve this problem, an attempt was made to control film formation of a light shielding film by sputtering so that an outer edge of a film forming region (thin film formation region) of a light shielding film is positioned inside a ridge line between a main surface of a substrate and a chamfered surface on the main surface of the substrate and outside the position where a ground pin contacts when set on an electron beam writing apparatus.

Conventionally, when controlling a region of a thin film to be formed on a main surface of a substrate, sputtering is performed with a masking plate disposed for masking a region on the substrate where the thin film is not desired. In other words, sputtering is performed with only a region on a main surface of a substrate where a thin film needs to be formed (may hereinafter be referred to as “design region”) exposed. By sputtering with a masking plate in contact with a main surface of a substrate, it is possible to avoid the formation of a thin film wrapping around a chamfered surface and a side surface of a substrate. In this case, however, the contact between the masking plate and the main surface of the substrate causes scratches and foreign substances on the substrate due to rubbing and friction. Therefore, sputtering is performed by placing a masking plate in a non-contact state with a main surface of a substrate. During such sputtering, most sputtering particles reach a main surface of a substrate in a direction that is inclined to some extent from the direction perpendicular to the main surface of the substrate. In addition, sputtering particles in a floated state exist in a sputtering apparatus. Due to these factors, it is inevitable that a certain number of sputtering particles go around a gap between a main surface of the substrate and a masking plate and deposit thereon. In other words, while a desired thickness of a thin film is formed on a design region on a main surface of a substrate after the sputtering is completed, the thin film, though thin, is formed slightly outside the boundary of the design region.

In particular, in forming a highly conductive thin film such as a light shielding film, a thin film is desired to be formed outside the position where a ground pin of an electron beam writing apparatus, etc. contacts. In many cases, the position where a ground pin contacts is close to a ridge line between a main surface of a substrate and a chamfered surface on the main surface of the substrate. When such a thin film needs to be formed in a region close to a ridge line between a main surface and a chamfered surface on the main surface, if the positional precision in placing a masking plate is low, sputtering particles may adhere to the chamfered surface or side surface to form a thin film thereto. In other words, it is necessary to improve the positional precision of a masking plate of a sputtering apparatus in order to control the thin film formation region.

As a method to confirm the positional precision of a masking plate, a masking plate was actually placed on a substrate and a light shielding film was formed by sputtering, and the region where the light shielding film was formed was magnified with an optical camera and visually identified. As a result, there were cases where the boundary between regions where the light shielding film was formed and not formed was difficult to confirm, which was a problem. Such a problem is not limited to light shielding films, but can also occur in masks for other applications having a thin film on a substrate.

The present disclosure was made to solve the conventional problems, and an aspect of the disclosure is to facilitate visual identification of the boundary between regions where a thin film is formed and not formed (region where a substrate is exposed) when the thin film is formed on a substrate. A further aspect is to provide a mask blank that can enable easy adjustment of the position of a masking plate to be disposed in a sputtering apparatus for forming a thin film so as to avoid formation of the thin film wrapping around a side surface or a chamfered surface of the substrate. A further aspect is to provide a transfer mask manufactured using this mask blank. Moreover, an aspect of the present disclosure is to provide a method of manufacturing a semiconductor device using the transfer mask.

### Means for Solving the Problem

For solving the above problems, the present disclosure includes the following configurations.

### (Configuration 1)

A mask blank including a substrate and a thin film, in which the substrate includes two main surfaces and a side surface with a chamfered surface provided between the two main surfaces and the side surface;

in which one main surface of the two main surfaces includes an inner region including a center of the main surface and an outer peripheral region outside of the inner region;

in which the thin film is provided on the inner region of the main surface;

in which a surface reflectance Rs of the outer peripheral region of the main surface with respect to light of 400 nm to 700 nm wavelength is 10% or less; and provided that Rf is a surface reflectance with respect to light of 400 nm to 700 nm wavelength in one section among sections of the thin film in the range of 9 nm to 10 nm film thickness, a contrast ratio (Rf/Rs) is 3.0 or more.

### (Configuration 2)

The mask blank according to Configuration 1, in which a surface reflectance of the one section with respect to the light of 400 nm to 700 nm wavelength is 20% or more.

### (Configuration 3)

The mask blank according to Configuration 1 or 2 in which, provided that RfB is a surface reflectance with respect to light of 400 nm wavelength at the one section, that RfG is a surface reflectance to light of 550 nm wavelength at the one section, and that RfR is a surface reflectance to light of 700 nm wavelength at the one section, a standard deviation calculated between the three surface reflectances RfB, RfG, and RfR is 1.0 or less.

### (Configuration 4)

The mask blank according to any of Configurations 1 to 3, in which the thin film has an extinction coefficient k of 1.5 or more with respect to the light of 400 nm to 700 nm wavelength.

### (Configuration 5)

The mask blank according to any of Configurations 1 to 4, in which an average film thickness of the thin film is greater than 10 nm and 60 nm or less.

### (Configuration 6)

The mask blank according to any of Configurations 1 to 5, in which an intermediate film is provided between the one main surface and the thin film in an interior region from an outer edge of the inner region to a center of the one main surface.

### (Configuration 7)

The mask blank according to Configuration 6, in which the intermediate film is a light-semitransmissive film that transmits exposure light of an ArF excimer laser with a transmittance of 1% or more.

### (Configuration 8)

A transfer mask provided with a transfer pattern in the thin film of the mask blank according to any of Configurations 1 to 5.

### (Configuration 9)

A transfer mask including a transfer pattern in the intermediate film of the mask blank of Configuration 6 or 7, and including a pattern including a light shielding band in the thin film.

### (Configuration 10)

A method of manufacturing a semiconductor device including the step of transferring a transfer pattern to a resist film on a semiconductor substrate by exposure using the transfer mask according to Configuration 8 or 9.

### Effect of the Disclosure

According to the mask blank of the present disclosure, it is possible to facilitate visual identification of the boundary between regions where a thin film is formed and not formed when the thin film is formed on a substrate. Accordingly, the position of a masking plate to be disposed in a sputtering apparatus for forming the thin film can be adjusted easily so as to avoid formation of the thin film wrapping around a side surface or a chamfered surface of the substrate.

### BRIEF DESCRIPTION OF THE DRAWINGS

FIG. 1 is a cross-sectional view of a principal portion showing a configuration of the mask blank of an embodiment of the present disclosure.

FIG. 2 is a schematic plan view of the substrate of an embodiment of the present disclosure.

FIGS. 3A-3G are schematic cross-sectional views showing a manufacturing process of the phase shift mask of an embodiment of the present disclosure.

FIG. 4 is a schematic view of a principal portion of the masking plate for use in forming the thin film of the mask blank of an embodiment of the present disclosure.

FIG. 5 is a graph showing a film thickness profile near the boundary between the main surface and the light shielding film in Example 1.

### EMBODIMENTS FOR CARRYING OUT THE DISCLOSURE

Before explaining the embodiment of the present disclosure, the background of the present disclosure is explained below.

The inventors diligently studied regarding a configuration of a mask blank in which, when a thin film was formed on a substrate, a boundary between a region where the thin film is formed and a region where the thin film is not formed (region where the substrate is exposed) is easily visually identified so as to facilitate positional adjustment of a masking plate to be provided in a sputtering apparatus for forming the thin film so as to avoid formation of the thin film wrapping around a side surface or a chamfered surface of the substrate.

Due to the aforementioned factors, when a thin film is formed by sputtering using a masking plate, it is inevitable that a certain number of sputtering particles go around a gap between the main surface of the substrate and the masking plate and deposit thereon. In other words, while the thin film is formed with a desired thickness in the design region on the main surfaces of the substrate, the thin film, though thin, is formed slightly outside the boundary of the design region. The formed thin film has substantially uniform thickness in the region of the main surface that is not covered by the masking plate. However, due to the influence of the sputtering particles entering the gap between the masking plate and the main surface of the substrate, the shape of an edge of the thin film lacks a vertical sidewall. Namely, an edge of the thin film is outside the design region of the main surface by a certain distance, and the thin film formed outside the design region is in a shape whose thickness becomes thinner from the position of the boundary of the design region toward its edge.

It is inevitable that the distance from the boundary of the design region of the main surface to the edge of the thin film varies even between two sputtering apparatuses with the same design specification. Even when the same sputtering apparatus is used, difference occurs depending on the sputtering conditions. Therefore, the position of the masking plate is adjusted by actually forming a thin film on a substrate above which the masking plate is disposed under the designed film forming conditions and checking the position of the edge of the thin film. Considering the relatively high frequency of adjusting the position of the masking plate, the inventors employed a method using image data captured by an imaging camera such as a CCD to identify the edge of the thin film (this method may hereinafter be referred to as “image identification method”). In using the image identification method, it is difficult to accurately detect the boundary between the regions on the main surface where the thin film is formed and not formed (region where the main surface is exposed). In the image identification method, a section is identified as having a thin film when the section has a certain level or more of contrast ratio between light reflected in the region where the thin film is not formed and light reflected in the region where the thin film is formed. The position of the outermost edge of the region where the thin film exists, as identified by the image identification method, is slightly inside the position of the outermost edge of the region where the thin film actually exists.

As a result of the diligent study of the inventors, it was discovered that depending on the configuration of the thin film, there is an increase in the difference between the position of the outermost edge of the region where the thin film exists as identified by the image identification method and the position of the outermost edge of the region where the thin film actually exists, resulting in less precise positioning of the masking plate. Therefore, the inventors further diligently studied the trend of the thickness of a thin film from a design region of a thin film formed by sputtering on a main surface of a substrate to the edge of the thin film, focusing on the relationship between the thickness of the thin film and the reflectance to visible light (specifically, light of 400 nm to 700 nm wavelength; light in this wavelength band may hereafter be referred to as “light in the visible light region”).

First, based on the trend of the thin film thickness, the inventors found that when the existence of a thin film can be identified at a section having the maximum thin film thickness of 10 nm by the image acquisition method given above, there is less difference from the position of the outermost edge of a region where the thin film actually exists, and the position of the masking plate can be adjusted with high precision. To facilitate identification of the existence of the thin film at that section of the thin film, it is expected to have a low surface reflectance to light in the visible light region in an outer peripheral region of a main surface of a substrate where a thin film is not formed. It was found that the surface reflectance is preferably 10% or less. In addition, the inventors found that, to enable identification of the existence of a thin film at that section of the thin film, the contrast ratio is preferably 3.0 or more between the surface reflectance to light in the visible light region at the section of the thin film and the surface reflectance to light in the visible light region at the section where the main surface of the substrate is exposed. It was also found that to facilitate identification of the existence of a thin film, it is preferable that the contrast ratio is maintained 3.0 or more even if the thickness of the thin film is reduced by 1 nm from 10 nm.

Namely, the mask blank of the present disclosure is a mask blank having a substrate and a thin film, featured in that the substrate includes two main surfaces and a side surface with a chamfered surface provided between the two main surfaces and the side surface, one main surface of the two main surfaces includes an inner region including a center of the main surface and an outer peripheral region outside of the inner region, the thin film is provided on an inner region of the main surface, a surface reflectance Rs of the outer peripheral region of the main surface with respect to light of 400 nm to 700 nm wavelength is 10% or less, and provided that Rf is a surface reflectance with respect to light of 400 nm to 700 nm wavelength in one section among sections of the thin film in the range of 9 nm to 10 nm film thickness, the contrast ratio (Rf/Rs) is 3.0 or more.

FIG. 1 is a cross-sectional view showing a configuration of a mask blank 100 of an embodiment of the present disclosure. The mask blank 100 of the present disclosure shown in FIG. 1 has a structure where a phase shift film 20, a light shielding film 30, and a hard mask film 31 are stacked in this order on a transparent substrate 10.

The transparent substrate 10 can be made of quartz glass, aluminosilicate glass, soda-lime glass, low thermal expansion glass (SiO₂—TiO₂ glass, etc.), etc., in addition to synthetic quartz glass. Among these materials, synthetic quartz glass is particularly preferable as a material for forming a transparent substrate of a mask blank for having high transmittance to ArF exposure light and having sufficient rigidity that is unlikely to cause a deformation. The substrate 10 to be received within a chamber (not shown) includes two main surfaces 11 (11a, 11b), a side surface 12, and a chamfered surface 13 formed by chamfering the boundary between the main surface 11 and the side surface 12. The boundary between the main surface 11 and the chamfered surface 13 is, when viewed from the main surface 11 side, preferably less than 0.5 mm from the side surface 12 of the substrate, and more preferably 0.4 mm or less.

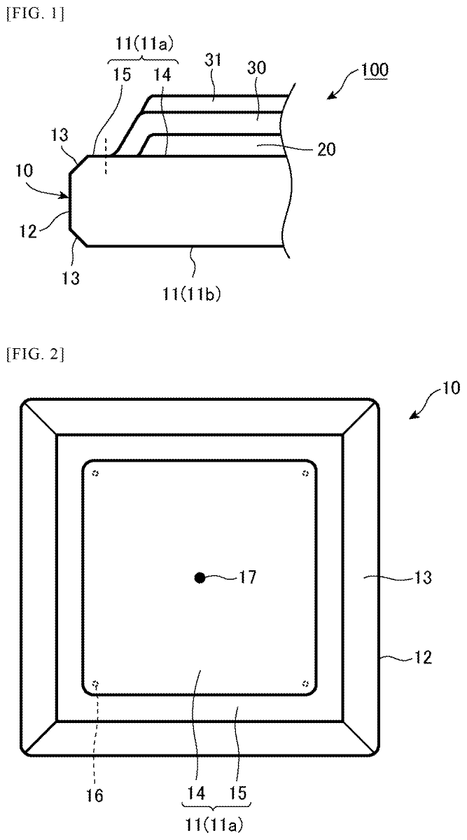

As shown in FIG. 2, one main surface 11a of the two main surfaces 11 includes an inner region 14 including a center 17 of the main surface 11a and an outer peripheral region 15 outside of the inner region 14. The light shielding film 30 as a thin film is provided on the inner region 14. On the outer peripheral region 15, the light shielding film 30 is not substantially formed, namely, the main surface 11a is substantially exposed. The state where the light shielding film 30 is not substantially formed or the state where the main surface 11a is substantially exposed includes the state where the sputtering particles configuring the light shielding film 30 are slightly adhered and deposited in less than 1 nm. Such a level of deposition hardly causes defects, and there is no substantial difference from the surface reflectance Rs in the state where the main surface 11a is fully exposed. To clarify, the boundary line between the inner region 14 and the outer peripheral region 15 and the center 17 shown in FIG. 2 are hypothetical which are applied for the purpose of explanation, and are not always actually applied to actual substrates.

The boundary line between the inner region 14 and the outer peripheral region 15 is preferably 0.05 mm or more inside the boundary between the chamfered surface 13 and the main surface 11a of the substrate 10.

Further, the surface reflectance Rs of the outer peripheral region 15 of the substrate 10 to light of 400 nm to 700 nm wavelength is preferably 10% or less, more preferably 8% or less, and even more preferably 7% or less. Both the surface reflectance Rs and the surface reflectance Rf described below can be measured based on image data captured by an imaging camera such as a CCD. With the surface reflectance Rs of the outer peripheral region 15 in the above range, it is easier to adjust the contrast ratio to 3.0 or more with respect to the surface reflectance Rf of the thin film to light of 400 nm to 700 nm wavelength when the film thickness of the thin film is within the range between 9 nm and 10 nm.

In this embodiment, as shown in FIG. 1, a phase shift film 20 as an intermediate film is provided, in an interior region extending from the boundary between the inner region 14 and the outer peripheral region 15 toward the center 17 of the main surface 11a, between the main surface 11a and the light shielding film 30 as the thin film.

The phase shift film 20 consists of a material containing silicon.

The phase shift film 20 is preferably a light-semitransmissive film having a function to transmit an exposure light of an ArF excimer laser at a transmittance of 1% or more (transmittance) and a function to generate a phase difference of 150 degrees or more and 210 degrees or less between an exposure light transmitted through the phase shift film 20 and the exposure light transmitted through the air by the same distance as the thickness of the phase shift film 20. Further, a transmittance of the phase shift film 20 is preferably 1% or more, and more preferably 2% or more. A transmittance of the phase shift film 20 is more preferably 30% or less, and even more preferably 20% or less.

The thickness of the phase shift film 20 is preferably 80 nm or less, and more preferably 70 nm or less. The thickness of the phase shift film 20 is preferably 50 nm or more. This is because 50 nm or more thickness is required to form the phase shift film 20 with an amorphous material while achieving a phase difference of the phase shift film 20 of 150 degrees or more.

For the phase shift film 20 to satisfy the conditions regarding the optical properties and film thickness mentioned above, the refractive index n of the phase shift film to an exposure light (ArF exposure light) is preferably 1.9 or more, and more preferably 2.0 or more. Further, the refractive index n of the phase shift film 20 is preferably 3.1 or less, and more preferably 2.7 or less. The extinction coefficient k of the phase shift film 20 to an ArF exposure light is preferably 0.26 or more, and more preferably 0.29 or more. Further, the extinction coefficient k of the phase shift film 20 is preferably 0.62 or less, and more preferably 0.54 or less.

Incidentally, the refractive index n and extinction coefficient k of the thin film including the phase shift film 20 are not determined only by the composition of the thin film. Film density and crystal condition of the thin film are also the factors that affect the refractive index n and extinction coefficient k. Therefore, the conditions in forming the thin film by reactive sputtering are adjusted so that the thin film has desired refractive index n and extinction coefficient k. For allowing the phase shift film 20 to have the refractive index n and extinction coefficient k within the above range, it is effective to adjust a ratio of mixed gas of noble gas and reactive gas (oxygen gas, nitrogen gas, etc.) in forming a film by reactive sputtering, but it is not limited thereto. Various other adjustments are made upon forming a film by reactive sputtering, such as pressure in a film forming chamber, power applied to the sputtering target, and positional relationship such as distance between the target and the transparent substrate 10. Further, these film forming conditions are unique to film forming apparatuses and are adjusted accordingly so that the phase shift film 20 to be formed has desired refractive index n and extinction coefficient k.

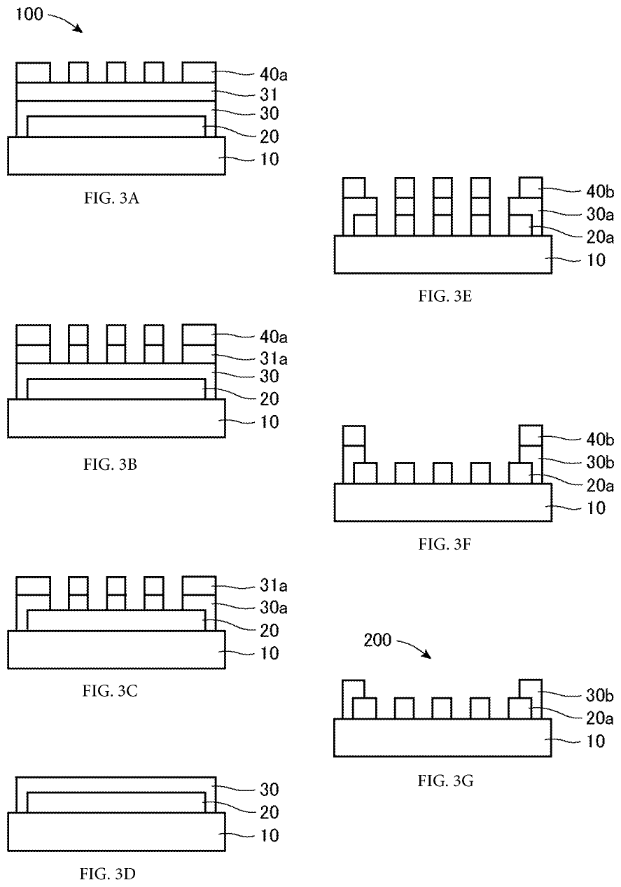

The mask blank 100 has a light shielding film 30 as a thin film on the phase shift film 20. Generally, in a binary transfer mask, an outer peripheral region of a region where a transfer pattern is formed (transfer pattern formation region) is desired to ensure an optical density (OD) of a predetermined value or more to prevent the resist film from being subjected to an influence of an exposure light that transmitted through the outer peripheral region when a transfer was made by exposure on the resist film on a semiconductor wafer using an exposure apparatus. This point is similarly applied to the case of the phase shift mask. Generally, the outer peripheral region of a transfer mask including a phase shift mask preferably has OD of 3.0 or more, and at least more than 2.0 is supposed to be necessary. The phase shift film 20 has a function to transmit an exposure light at a predetermined transmittance, and it is difficult to ensure an optical density of a predetermined value with the phase shift film 20 alone. Therefore, it is supposed to be necessary to stack the light shielding film 30 on the phase shift film 20 to secure optical density that would otherwise be insufficient at the stage of manufacturing the mask blank 100. With such a configuration of the mask blank 100, the phase shift mask 200 securing a predetermined value of optical density on the outer peripheral region can be manufactured by removing the light shielding film 30 of the region which uses the phase shift effect (basically transfer pattern formation region) during manufacture of the phase shift mask 200 (see FIGS. 3A-3G).

Further, the light shielding film 30 should function as an etching mask upon dry etching by fluorine-based gas for forming a transfer pattern (phase shift pattern) in the phase shift film 20. Therefore, the light shielding film 30 should be made from materials having sufficient etching selectivity to the phase shift film 20 upon dry etching by fluorine-based gas. It is expected for the light shielding film 30 to precisely form a fine pattern to be formed in the phase shift film 20. The average film thickness of the light shielding film 30 is preferably 60 nm or less, more preferably 50 nm or less, and further preferably 40 nm or less. When the film thickness of the light shielding film 30 is too thick, the fine pattern to be formed cannot be created with high precision. On the other hand, it is expected for the light shielding film 30 to satisfy the expected optical density as given above. Therefore, the average film thickness of the light shielding film 30 is expected to be greater than 10 nm, and more preferably 15 nm or more, excluding the edge region that is the boundary between the inner region 14 and the outer peripheral region 15. While the average film thickness is not particularly limited, the average film thickness can be calculated by dividing the region where the light shielding film 30 is formed into areas of about 55 μm×about 55 μm, and taking an average of the film thickness measured in each area.

In this embodiment, the light shielding film 30 as the thin film is configured such that, provided that Rf is a surface reflectance to light of 400 nm to 700 nm wavelength in one section among sections of the light shielding film 30 in the range of 9 nm to 10 nm film thickness, the contrast ratio (Rf/Rs) is 3.0 or more. This facilitates identification of the boundary between regions where the light shielding film 30 as the thin film is formed and not formed. From the viewpoint of visibility, the surface reflectance Rf of the one section to the light of 400 nm to 700 nm wavelength is preferably 20% or more.

As mentioned above, the section of the light shielding film 30 (thin film) for defining the surface reflectance Rf is not exactly the outermost edge of the light shielding film 30. However, the difference from the position of the section of the light shielding film 30 to the position of the outermost edge is small, and it is sufficiently possible to adjust the position of the masking plate based on the position of the section.

From the viewpoint of ensuring conductivity, the sheet resistance of the light shielding film 30 is preferably 1 kΩ/square or less, and more preferably 0.5 kΩ/square or less.

In the light shielding film 30, provided that RfB is the surface reflectance to light of 400 nm wavelength at one section among sections of the thin film in the range of 9 nm to 10 nm film thickness, that RfG is the surface reflectance to light of 550 nm wavelength at the one section, and that RfR is the surface reflectance to light of 700 nm wavelength at the one section, the standard deviation calculated between the three surface reflectances RfB, RfG, and RfR is preferably 1.0 or less. The standard deviation can be obtained relatively easily from the RGB values of image data captured by an imaging camera such as a CCD. The smaller the deviation of each reflectance to the three wavelengths of light, the easier it is to view the existence of the light shielding film 30.

From the viewpoint of visibility, the extinction coefficient k of the light shielding film 30 to the light of 400 nm to 700 nm wavelength is preferably 1.5 or more, and more preferably 2.0 or more. Further, the extinction coefficient k of the light shielding film 30 to the above light is preferably 4.0 or less, and more preferably 3.5 or less.

A single layer structure and a stacked structure of two or more layers are applicable to the light shielding film 30. Further, each layer in the light shielding film of a single layer structure and the light shielding film of a stacked structure of two or more layers can be configured by approximately the same composition in the thickness direction of the layer or the film, or with a composition gradient in the thickness direction of the layer.

The light shielding film 30 can be formed of any material as long as the condition of the contrast ratio given above is satisfied. The light shielding film 30 is preferably made of a material containing chromium. Materials containing chromium for forming the light shielding film 30 can include, in addition to chromium metal, a material containing chromium (Cr) and one or more elements selected from oxygen (O), nitrogen (N), carbon (C), boron (B), and fluorine (F). While a chromium-based material is generally etched by mixed gas of chlorine-based gas and oxygen gas, an etching rate of a chromium metal with respect to the etching gas is not so high. Considering enhancing an etching rate with respect to etching gas as mixed gas of chlorine-based gas and oxygen gas, a material for forming the light shielding film 30 preferably contains chromium and one or more elements selected from oxygen, nitrogen, carbon, boron, and fluorine. Further, one or more elements among molybdenum, indium, and tin can be included in the material containing chromium for forming the light shielding film 30. Including one or more elements among molybdenum, indium, and tin can further increase an etching rate to mixed gas of chlorine-based gas and oxygen gas.

The light shielding film 30 can be formed on the phase shift film 20 by reactive sputtering method using a target containing chromium. As the sputtering method, a sputtering using direct current (DC) power source (DC sputtering), or a sputtering using radio-frequency (RF) power source (RF sputtering) can be used. In addition, magnetron sputtering method and conventional method can also be used. DC sputtering is preferable for having a simple mechanism. A magnetron sputtering method is preferable for increasing the deposition rate and enhancing productivity. Incidentally, a film-forming apparatus can be an in-line type or a single-wafer type.

As sputtering gas to be used in forming the light shielding film 30, preferable gas is one of mixed gas of gas free of oxygen and containing carbon (CH₄, C₂H₄, C₂H₆, etc.), gas free of carbon and containing oxygen (O₂, O₃, etc.), and noble gas (Ar, Kr, Xe, He, Ne, etc.); mixed gas of gas containing carbon and oxygen (CO₂, CO, etc.) and noble gas; or mixed gas of gas containing noble gas, carbon, and oxygen and at least one of gas free of oxygen and containing carbon (CH₄, C₂H₄, C₂H₆, etc.) and gas free of carbon and containing oxygen. Particularly, it is safe to use mixed gas of CO₂ and noble gas as sputtering gas, and since CO₂ gas can be distributed uniformly through a wide range in a chamber for being less reactive than oxygen gas, it is preferable in view of maintaining uniform film quality of the light shielding film 30 to be formed. As for the introduction method, the gas can be introduced separately into the chamber, or some gas can be introduced together or all gas can be introduced in mixture.

Materials of the target can include, not only a simple chromium, but also chromium as a major substance, and chromium including any one of oxygen and carbon, or a combination of oxygen and carbon added to chromium can be used as the target.

Incidentally, the mask blank of the present disclosure is not limited to those shown in FIG. 1, but can be configured to have an additional film (etching stopper film) intervening between the phase shift film 20 and the light shielding film 30. In this case, a preferable configuration is that the etching stopper film is formed from the material containing chromium given above, and that the light shielding film 30 is formed from a material containing silicon or a material containing tantalum.

The mask blank of the present disclosure is not limited to the mask blank for the phase shift mask described above, and can be applied to a mask blank for a binary mask. The mask blank in this case has a configuration without the phase shift film 20 between the main surface 11a of the transparent substrate 10 and the light shielding film 30. Further, the predetermined optical density is secured by the light shielding film 30 alone. A binary mask (transfer mask) can be formed by forming a transfer pattern in the light shielding film 30 of such a mask blank.

Further, the mask blank of the present disclosure can be a reflective mask blank for EUV lithography (Extreme Ultraviolet Lithography). In this case, an absorber film is preferably configured from the thin film in this embodiment.

A material containing silicon for forming the light shielding film 30 can include a transition metal, and can include metal elements other than a transition metal. The reason is that substantial problems hardly occur even if ArF light fastness is low since the pattern formed in the light shielding film 30 is basically a light shielding band pattern formed in an outer peripheral region where accumulation of irradiation of an ArF exposure light is less than that in a transfer pattern region, and that a fine pattern is rarely arranged in the outer peripheral region. Another reason is that including a transition metal in the light shielding film 30 significantly enhances light shielding performance compared to the case without a transition metal, which enables a reduction of the thickness of the light shielding film 30. Transition metals to be included in the light shielding film 30 include any one of metals such as molybdenum (Mo), tantalum (Ta), tungsten (W), titanium (Ti), chromium (Cr), hafnium (Hf), nickel (Ni), vanadium (V), zirconium (Zr), ruthenium (Ru), rhodium (Rh), niobium (Nb), and palladium (Pd), or a metal alloy thereof.

The mask blank 100 can be configured such that the light shielding film 30 has further stacked thereon a hard mask film 31 made of a material having an etching selectivity to etching gas used in etching the light shielding film 30. Since the hard mask film 31 is formed in a region inward compared to the light shielding film 30 as shown in FIG. 1, there is no hindrance in securing conductivity of the light shielding film 30 and the resist film. It is sufficient for the hard mask film 31 to have the film thickness enough to function as an etching mask until dry etching for forming a pattern in the light shielding film 30 directly therebelow is completed, and basically the hard mask film 31 is not limited with regard to optical density. Therefore, the thickness of the hard mask film 31 can be reduced significantly compared to the thickness of the light shielding film 30. Since a resist film of an organic material only requires the film thickness to function as an etching mask until dry etching for forming a pattern in the hard mask film is completed, the thickness can be reduced significantly compared to conventional resist films. Reduction of the film thickness of a resist film is effective for enhancing resist resolution and preventing collapse of pattern, which is extremely important in facing the requirements for miniaturization.

In the case where the light shielding film 30 is formed of a material containing chromium, the hard mask film 31 is preferably formed of the material containing silicon given above. Since the hard mask film 31 in this case tends to have low adhesiveness with a resist film of an organic material, it is preferable to treat the surface of the hard mask film 31 with HMDS (Hexamethyldisilazane) to enhance surface adhesiveness. The hard mask film in this case is more preferably formed of SiO₂, SiN, SiON, etc.

Further, in the case where the light shielding film 30 is formed of a material containing chromium, materials containing tantalum are also applicable as materials of the hard mask film 31, in addition to the materials given above. Examples of the material containing tantalum in this case include, in addition to tantalum metal, a material containing tantalum and one or more elements selected from nitrogen, oxygen, boron, carbon, and silicon, for example, Ta, TaN, TaO, TaON, TaBN, TaBO, TaBON, TaCN, TaCO, TaCON, TaBCN, TaBOCN, TaSi, TaSiN, TaSiO, TaSiON, TaSiBN, TaSiBO, TaSiBON, TaSiC, TaSiCN, TaSiCO, TaSiCON, etc. Further, in the case where the light shielding film 30 is formed of a material containing silicon, the hard mask film 31 is preferably formed of the material containing chromium given above.

In the mask blank 100, a resist film made of an organic-based material can be formed in contact with a surface of the light shielding film 30 (in contact with the surface of the hard mask film 31 when the hard mask film is formed). In the case of a fine pattern compatible with the DRAM hp32 nm generation, SRAF (Sub-Resolution Assist Feature) having a line width of 40 nm may be provided in a light shielding pattern to be formed in the light shielding film 30. However, in this case as well, as described above, the film thickness of the resist film can be restrained as a result of providing the hard mask film 31, and as a consequence, a cross-sectional aspect ratio of the resist pattern formed of the resist film can be set as low as 1:2.5. Therefore, collapse or peeling of the resist pattern during development, rinsing, etc. of the resist film can be reduced. Incidentally, the resist film preferably has the film thickness of 80 nm or less. The resist film is preferably a resist for electron beam writing exposure, and it is more preferable that the resist is a chemically amplified resist.

The mask blank 100 of the above configuration is manufactured by the following procedure. First, a transparent substrate 10 is prepared. This transparent substrate 10 includes a side surface 12 and main surfaces 11 polished into a predetermined surface roughness (e.g., root mean square roughness Rq of 0.2 nm or less in an inner region of a square of 1 μm side), and thereafter subjected to predetermined cleaning treatment and drying treatment.

Next, a phase shift film 20 is formed on the transparent substrate 10 by sputtering method. After the phase shift film 20 is formed, annealing is carried out at a predetermined heating temperature. Next, the light shielding film 30 is formed on the phase shift film 20 by the sputtering method.

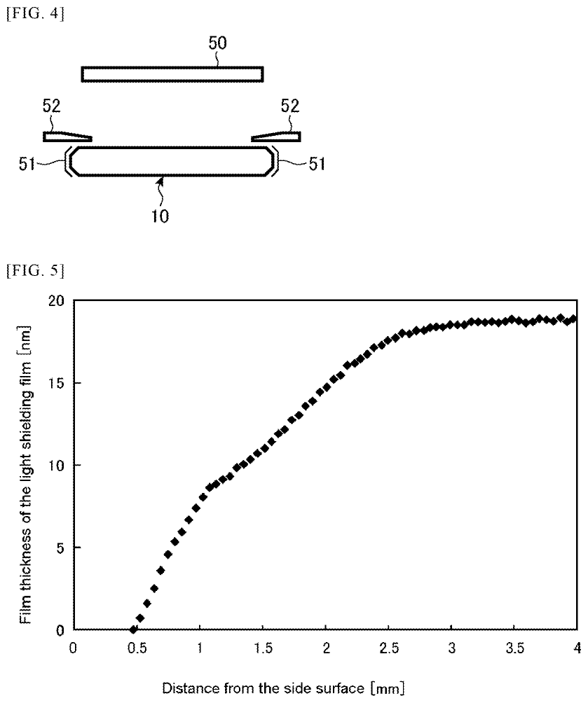

A principal part of a masking plate used in forming the light shielding film 30 is shown in FIG. 4. As shown in FIG. 4, the substrate 10 is positioned and retained at its ends by substrate retaining portions 51. Shielding plates 52 are provided above the substrate 10 to cover the periphery of the substrate 10. The shielding plates 52 are provided to be positionable toward or away from the center 17 of the main surface 11a of the substrate 10 while keeping a non-contact state with the substrate 10. By adjusting the position of the shielding plates 25, it is possible to restrain the light shielding film material supplied from a sputtering target 50 from adhering to the periphery of the substrate 10.

Subsequently, the hard mask film 31 is formed on the light shielding film 30 by sputtering method. In formation of each layer by sputtering method, a sputtering target containing materials forming each layer at a predetermined composition ratio and sputtering gas are used, and moreover, the mixed gas of noble gas and reactive gas mentioned above is used as sputtering gas as necessary. Thereafter, in the case where the mask blank 100 includes a resist film, the surface of the hard mask film 31 is subjected to a HMDS (Hexamethyldisilazane) treatment as necessary. Next, a resist film is formed by coating methods such as spin coating on the surface of the hard mask film 31 after the HMDS treatment to complete the mask blank 100.

The phase shift mask 200 as a transfer mask of this embodiment is featured in that a transfer pattern (phase shift pattern) 20a is formed in the phase shift film 20 of the mask blank 100, and a light shielding pattern 30b including a light shielding band is formed in the light shielding film 30. In the case of a configuration where a hard mask film is provided in the mask blank 100, the hard mask film 31 is removed during manufacture of the phase shift mask 200.

The method of manufacturing the phase shift mask 200 of the present disclosure uses the mask blank 100 mentioned above, featured in including the steps of forming a transfer pattern in the light shielding film 30 by dry etching; forming a transfer pattern in the phase shift film 20 by dry etching with the light shielding film 30 having the transfer pattern as a mask; and forming a light shielding pattern 30b in the light shielding film 30 by dry etching with a resist film (resist pattern 40b) having a light shielding band pattern as a mask. The method of manufacturing the phase shift mask 200 of the present disclosure is explained below according to the manufacturing steps shown in FIGS. 3A-3G.

First, a resist film is formed on the hard mask film 31 of the mask blank 100 by spin-coating method. Next, a first pattern (phase shift pattern) to be formed in the phase shift film 20 is written on the resist film by exposure with electron beam. At this stage, a ground pin (not shown) is in contact with the light shielding film 30 having the resist film formed thereon, and a ground is secured between the resist film and the light shielding film 30 (see the ground pin grounding location 16 in FIG. 2). Thus, a charge up upon exposure writing can be restrained. Thereafter, the resist film is subjected to predetermined treatments such as a PEB treatment, a developing treatment, and a post-baking treatment, and the first resist pattern 40a corresponding to the phase shift pattern is formed in the resist film (see FIG. 3A).

Next, dry etching of the hard mask film 31 is carried out using fluorine-based gas with the resist pattern 40a as a mask, and a hard mask pattern 31a as a first pattern is formed in the hard mask film 31 (see FIG. 3B). Thereafter, the resist pattern 40a is removed. Incidentally, dry etching of the light shielding film 30 can be carried out with the resist pattern 40a remaining. In such a case, the resist pattern 40a is eliminated upon dry etching of the light shielding film 30.

Next, dry etching using oxygen-containing chlorine-based gas is carried out using the hard mask pattern 31a as a mask, and a light shielding pattern 30a as a first pattern is formed in the light shielding film 30 (see FIG. 3C). Mixing ratio of mixed gas of chlorine-based gas and oxygen gas in dry etching of the light shielding film 30 is, at gas flow ratio in an etching apparatus, preferably chlorine-based gas: oxygen gas=10 or more: 1, more preferably 15 or more: 1, and further preferably 20 or more: 1. By using etching gas with high mixing ratio of chlorine-based gas, anisotropic property of dry etching can be enhanced. Further, in dry etching of the light shielding film 30, mixing ratio of mixed gas of chlorine-based gas and oxygen gas is, at gas flow ratio in an etching chamber, preferably chlorine-based gas: oxygen gas=40 or less: 1.

Subsequently, dry etching is carried out using fluorine-based gas with the light shielding pattern 30a as a mask, a phase shift pattern 20a as a first pattern is formed in the phase shift film 20, and the hard mask pattern 31a is removed (see FIG. 3D). Next, a resist film is formed on the light shielding pattern 30a by spin coating. On the resist film, a light shielding pattern as a second pattern to be formed in the light shielding film 30 is written by exposure with electron beam. Thereafter, predetermined treatments such as a developing treatment are carried out, and a resist film having a resist pattern 40b as a second pattern corresponding to the light shielding pattern is formed (see FIG. 3E).

Next, dry etching is carried out using mixed gas of chlorine-based gas and oxygen gas with the resist pattern 40b as a mask, and a light shielding pattern 30b as a second pattern is formed in the light shielding film 30 (see FIG. 3F). Further, the resist pattern 40b is removed, predetermined treatments such as cleaning are carried out, and the phase shift mask 200 is obtained (see FIG. 3G).

Incidentally, there is no particular limitation to chlorine-based gas used in the dry etching in the manufacturing process described above, as long as Cl is included. Examples of chlorine-based gas include Cl₂, SiCl₂, CHCl₃, CH₂Cl₂, CCl₄, BCl₃, and the like. Further, there is no particular limitation to fluorine-based gas used in the dry etching in the manufacturing process described above, as long as F is included. Examples of fluorine-based gas include CHF₃, CF₄, C₂F₆, C₄F₈, SF₆, and the like. Particularly, fluorine-based gas free of C can further reduce damage on a glass substrate for having a relatively low etching rate to a glass substrate.

The phase shift mask 200 of the present disclosure is manufactured using the mask blank 100 mentioned above. Accordingly, a ground can be secured relative to the resist and generation of dust can be restrained. Thus, a good pattern transfer can be performed.

The method of manufacturing a semiconductor device of the present disclosure is featured in including the step of using the phase shift mask 200 given above or the phase shift mask 200 manufactured using the mask blank 100 given above, and transferring a transfer pattern on a resist film on a semiconductor device by exposure. Therefore, when the phase shift mask 200 is set on an exposure apparatus and an ArF exposure light is irradiated from the side of the transparent substrate 1 of the phase shift mask 200 to perform transfer on an object to be transferred (resist film on semiconductor wafer, etc.) by exposure, a desired pattern can be transferred to the object to be transferred with a high precision.

### EXAMPLES

The embodiment of the present disclosure is described in greater detail below together with examples.

### Example 1

### [Manufacture of Mask Blank]

In view of FIG. 1, a transparent substrate 1 made of a synthetic quartz glass with a size of main surfaces of about 152 mm×about 152 mm and the thickness of about 6.35 mm was prepared. Main surfaces of the transparent substrate 10 were polished to a predetermined surface roughness (0.2 nm or less Rq), and thereafter subjected to predetermined cleaning treatment and drying treatment. The transparent substrate 10 has two main surfaces 11 and four side surfaces 12 with a chamfered surface 13 between the main surfaces 11 and the side surfaces 12. The boundary (ridgeline) between the chamfered surface 13 and the main surfaces 11 is positioned close to the center 17 from the side surfaces 12 of the substrate by 0.4 mm, viewed from the main surfaces 11 side. At the plurality of locations on the main surface 11a of the transparent substrate 10, the surface reflectance Rs to the light of 400 nm to 700 nm wavelength was measured, resulting in 7% or less in any region (wavelength 400 nm: 6.99%, wavelength 550 nm: 6.75%, wavelength 700 nm: 6.62%).

Next, the transparent substrate 10 was placed in a single-wafer DC sputtering apparatus, and by reactive sputtering (DC sputtering) using a mix-sintered target of molybdenum (Mo) and silicon (Si) (Mo:Si=11atom %:89atom %) and with mixed gas of argon (Ar), nitrogen (N₂), and helium (He) as sputtering gas, a phase shift film 20 formed from molybdenum, silicon, and nitrogen was formed with the thickness of 69 nm on the transparent substrate 10. A masking plate as shown in FIG. 4 was used in sputtering for forming the phase shift film 20. The masking plate used has a square opening having a 146 mm side based on the center of the substrate.

Next, the transparent substrate 10 having the phase shift film 20 formed thereon was subjected to heat treatment for reducing film stress of the phase shift film 20 and for forming an oxidization layer on the surface layer. Specifically, the heat treatment was carried out using a heating furnace (electric furnace) at a heating temperature of 450° C. in the atmosphere for one hour. The transmittance and phase difference of the phase shift film 20 after the heat treatment to a light of 193 nm wavelength were measured using a phase shift measurement apparatus (MPM193 manufactured by Lasertec), and the transmittance was 6.0% and the phase difference was 177.0 degrees.

Next, the transparent substrate 10 having the phase shift film 20 formed thereon was placed in a single-wafer DC sputtering apparatus, and reactive sputtering (DC sputtering) was carried out using a chromium (Cr) target under a mixed gas atmosphere of argon (Ar), carbon dioxide (CO₂), and helium (He). Thus, a light shielding film (CrOC film) 30 formed from chromium, oxygen, and carbon was formed with the film thickness of 18 nm in contact with the phase shift film 20. A masking plate was used in sputtering for forming the light shielding film 30 as well. However, the masking plate used herein has a square opening having a 150 mm side based on the center of the substrate (i.e., the design region is a square region having a 150 mm side). The size of one side of the main surfaces 11 of the substrate is 151.2 mm, having significantly small tolerance with the design region.

Next, the transparent substrate 10 having the light shielding film (CrOC film) 30 formed thereon was subjected to heat treatment. Specifically, the heat treatment was carried out using a hot plate at a heating temperature of 280° C. in the atmosphere for five minutes. After the heat treatment, a spectrophotometer (Cary4000 manufactured by Agilent Technologies) was used on the transparent substrate 10 having the phase shift film 20 and the light shielding film 30 stacked thereon to measure optical density of the stacked structure of the phase shift film 20 and the light shielding film 30 under ArF excimer laser light wavelength (about 193 nm), confirming that the optical density exceeds 2.0.

Next, for each of the four corners of the main surface 11a of the transparent substrate 10 on which the light shielding film 30 was formed, enlarged image data was acquired using a CCD camera. The boundary between the light shielding film 30 and the main surface 11a could be viewed in each of the acquired image data. However, in each image data of the four corners, there were areas where the main surface 11a was entirely covered with the light shielding film 30 (the light shielding film 30 may have been wrapping around the chamfered surface 13). Namely, it was found that the masking plate was not disposed in the proper position. Therefore, for each image data of the four corners, distances to the boundary between the region where the main surface 11a is exposed (region where the light shielding film 30 is not formed) and the region where the light shielding film 30 is formed were calculated, respectively, based on the side surface 12. From this result, the difference between the center 17 of the transparent substrate 10 and the center of the masking plate during sputtering was calculated, and the position to dispose the masking plate was finely adjusted.

Next, another transparent substrate 10 was prepared, and a phase shift film 20 and a light shielding film 30 were formed by sputtering by the same procedure as above. Further, each image data was acquired, by the same procedure as above, for the four corners of the main surface 11a of the transparent substrate 10 on which the light shielding film 30 was formed. Thereafter, for each image data of the four corners, distances to the boundary between the region where the main surface 11a is exposed and the region where the light shielding film 30 is formed were calculated, respectively, based on the side surface 12, by the same procedure as above. As a result, in all of the four corners, the boundary between the region where the main surface 11a is exposed and the region where the light shielding film 30 was formed could be viewed. Further, the distances to the boundary based on the side surface 12 were generally the same.

Next, a film thickness profile near the boundary between the main surface 11a and the light shielding film 30 was measured with a contact-type microfigure measuring instrument (Kosaka Laboratory Ltd. ET-4000). The result is shown in FIG. 5. The result shows that the light shielding film 30 began to form from the position at a distance between 0.47 mm and 0.53 mm from the side surface 12 on the main surface 11a toward the interior. The surface reflectance Rf to the light of 400 nm to 700 nm wavelength of a plurality of measured sections (sections) of the light shielding film 30 between the thickness of 9 nm and 10 nm was measured from the image data, and the average was 23.65%, and the surface reflectance Rf to the light of wavelength within the above range was 20% or more in all cases. Further, the contrast ratio of the surface reflectance Rf of the light shielding film 30 at the above measured sections to the surface reflectance Rs of the main surface 11a (Rf/Rs) was calculated, resulting in at least 3.29, which was 3.0 or more. Furthermore, at the measured section where the surface reflectance Rf was the maximum (24.69%), the surface reflectance RfB to the light of 400 nm wavelength was 24.96%, the surface reflectance RfG to the light of 550 nm wavelength was 25.06%, and the surface reflectance RfR to the light of 700 nm wavelength was 24.08%. The standard deviation calculated between the three surface reflectances RfB, RfG, and RfR was 0.441, which was 1.0 or less.

The region where the light shielding film 30 is formed (i.e., the inner region 14) was divided into 55 μm×55 μm areas, and by taking an average of the film thickness measured in each area, the average film thickness of the light shielding film 30 was calculated. The calculated average film thickness of the light shielding film 30 was 18 nm.

Next, another transparent substrate 10 was prepared, and a phase shift film 20 was formed by sputtering by the same procedure as above and a light shielding film 30 was formed by sputtering on the position to dispose the masking plate after the fine adjustment. Next, the transparent substrate 10 having the phase shift film 20 and the light shielding film 30 stacked thereon was placed in a single-wafer DC sputtering apparatus, and by reactive sputtering (DC sputtering) using silicon (Si) target and in a mixed gas atmosphere of argon (Ar) and nitrogen monoxide (NO), a hard mask film 31 consisting of silicon, nitrogen, and oxygen was formed with the thickness of 5 nm, on the light shielding film 30 and inside the edge of the light shielding film 30. At this stage, a masking plate was used which has a square opening having a 146 mm side based on the center of the substrate. Further, a predetermined cleaning treatment was carried out to form a mask blank 100 of Example 1.

Another transparent substrate 10 was prepared, which has a light shielding film 30 formed on a main surface 11a under the same conditions without the other films, and which was subjected to heat treatment. The sheet resistance of the light shielding film 30 was measured, resulting in 0.246 kΩ/Square, which was 0.5 kΩ/Square or less. Further, the refractive index n and extinction coefficient k of the light shielding film 30 to the light of 400 nm to 700 nm wavelength were measured using a spectroscopic ellipsometer. As a result, the extinction coefficient k to the light of 400 nm wavelength was 2.33, the extinction coefficient k to the light of 550 nm wavelength was 2.53, and the extinction coefficient k to the light of 700 nm wavelength was 3.01, and the values were confirmed as 2.0 or more. The refractive index n to the light of 400 nm wavelength was 2.52, the refractive index n to the light of 550 nm wavelength was 2.96, and refractive index n to the light of 700 nm wavelength was 3.57.

Further, the light shielding film 30 was analyzed by an X-ray photoelectron spectroscopy (XPS; with RBS corrections). As a result, it was confirmed that the region near the surface that is opposite to the transparent substrate 10 side of the light shielding film 30 (region up to about 2 nm depth from the surface) has a composition gradient portion having more oxygen content (40atom % or more oxygen content) than the other regions. Further, the content of each constituent element in the region of the light shielding film 30 excluding the composition gradient portion was found to be, at an average value, Cr:71atom %, O:14atom %, and C:15atom %. Moreover, it was confirmed that the difference of each constituent element in the thickness direction of the region of the light shielding film 30 excluding the composition gradient portion was 3atom % or less in all cases, and there was substantially no composition gradient in the thickness direction.

Next, a half tone phase shift mask 200 of Example 1 was manufactured by the following procedure using the mask blank 100 of Example 1. First, a surface of a hard mask film 31 was subjected to a HMDS treatment. Subsequently, a resist film of a chemically amplified resist for electron beam writing was formed with the film thickness of 80 nm in contact with the surface of the hard mask film 31 by spin coating. Next, a first pattern as a phase shift pattern to be formed in the phase shift film 20 was written by an electron beam on the resist film, predetermined developing and cleaning treatments were conducted, and a resist pattern 40a having the first pattern was formed (see FIG. 3A). During the electron beam writing, the light shielding film 30 was contacted with a ground pin (not shown) at a ground pin grounding location 16. Thus, an electron beam was written on the resist film in a predetermined position, and a desired resist pattern 40a could be formed.

Next, dry etching using CF₄ gas was conducted with the resist pattern 40a as a mask, and a hard mask pattern 31a as a first pattern was formed in the hard mask film 31 (see FIG. 3B).

Next, the resist pattern 40a was removed. Subsequently, dry etching was conducted using the hard mask pattern 31a as a mask, with mixed gas of chlorine gas (Cl₂) and oxygen gas (O₂) (gas flow ratio Cl₂:O₂=13:1), and a light shielding pattern 30a as a first pattern was formed in the light shielding film 30 (see FIG. 3C).

Next, dry etching was conducted with the light shielding pattern 30a as a mask using fluorine-based gas (SF₆+He), and a phase shift pattern 20a as a first pattern was formed in the phase shift film 20, and also in this process, the hard mask pattern 31a was removed (see FIG. 3D).

Next, a resist film of a chemically amplified resist for electron beam writing was formed with the film thickness of 150 nm on the light shielding pattern 30a by spin coating. Next, a second pattern as a pattern (pattern including light shielding band pattern) to be formed in the light shielding film was written by exposure in the resist film, predetermined treatments such as developing were carried out, and a resist pattern 40b having the light shielding pattern was formed (see FIG. 3E). Subsequently, dry etching was conducted using the resist pattern 40b as a mask with mixed gas of chlorine gas (Cl₂) and oxygen gas (O₂) (gas flow ratio Cl₂:O₂=4:1), and a light shielding pattern 30b as a second pattern was formed in the light shielding film 30 (see FIG. 3F). Further, the resist pattern 40b was removed, predetermined treatments such as cleaning were carried out, and the phase shift mask 200 was obtained (see FIG. 3G).

On the phase shift mask 200 manufactured by the above procedure, a simulation of a transfer image was made using AIMS193 (manufactured by Carl Zeiss) assuming that an exposure transfer was made on a resist film on a semiconductor device at an exposure light of 193 nm wavelength. The simulated exposure transfer image was inspected, and the design specification was fully satisfied. It can be considered from this result that a circuit pattern to be finally formed on the semiconductor device can be formed at a high precision when the phase shift mask 200 of Example 1 was set on a mask stage of an exposure apparatus and a resist film on the semiconductor device was transferred by exposure.

### Comparative Example 1

### [Manufacture of Mask Blank]

A mask blank of Comparative Example 1 was manufactured by the process similar to that of Example 1, except for the light shielding film. A light shielding film of Comparative Example 1 has film forming conditions that are different from that of the light shielding film 3 of Example 1. Specifically, a transparent substrate having a phase shift film formed thereon was placed in a single-wafer DC sputtering apparatus, and reactive sputtering (DC sputtering) was carried out using a chromium (Cr) target under a mixed gas atmosphere of argon (Ar), carbon dioxide (CO₂), and helium (He). Thus, a light shielding film consisting of chromium, oxygen, and carbon (CrOC film) was formed with the film thickness of 24 nm in contact with the phase shift film. Similarly to the case of Example 1, a masking plate with a square opening having a 150 mm side was used in sputtering for forming the phase shift film 30.

Next, a transparent substrate having the light shielding film (CrOC film) formed thereon was subjected to heat treatment with the same conditions as Example 1. After the heat treatment, a spectrophotometer (Cary4000 manufactured by Agilent Technologies) was used on the transparent substrate having the phase shift film and the light shielding film stacked thereon to measure an optical density of the stacked structure of the phase shift film and the light shielding film under an ArF excimer laser light wavelength (about 193 nm), confirming the optical density of 3.0 or more.

Next, for each of the four corners of the main surface of the transparent substrate on which the light shielding film of Comparative Example 1 was formed, enlarged image data was acquired using a CCD camera by the procedure similar to that of Example 1. However, the boundary between the light shielding film and the main surface was difficult to view in each of the acquired image data. Therefore, it was difficult to calculate the difference between the center 17 of the transparent substrate 10 and the center of the masking plate during sputtering, and to finely adjust the position to dispose the masking plate with high precision.

Next, a film thickness profile near the boundary between the main surface and the light shielding film of Comparative Example 1 was measured with a contact-type microfigure measuring instrument (Kosaka Laboratory Ltd. ET-4000). The surface reflectance Rf to the light of 400 nm to 700 nm wavelength of a plurality of measured sections (sections) of the light shielding film between the thickness of 9 nm and 10 nm was measured from the image data, and the average was 14.85%, and the surface reflectance Rf to the light of wavelength within the above range was significantly below 20% in all cases. Further, the contrast ratio of the surface reflectance Rf of the light shielding film of the Comparative Example 1 at the above measured sections to the surface reflectance Rs of the main surface (Rf/Rs) was calculated, resulting in 2.27 at the most, which was significantly below 3.0. Furthermore, at the measured sections where the surface reflectance Rf was the maximum (15.51%), the surface reflectance RfB to the light of 400 nm wavelength was 17.85%, the surface reflectance RfG to the light of 550 nm wavelength was 15.37%, and the surface reflectance RfR to the light of 700 nm wavelength was 13.32%. The standard deviation calculated between the three surface reflectances RfB, RfG, and RfR was 1.853, which was significantly above 1.0.

Further, the region where the light shielding film 30 is formed (i.e., the inner region 14) was divided into 55 μm×55 μm areas, and by taking an average of the film thickness measured in each area, the average film thickness of the light shielding film 30 was calculated. The calculated average film thickness of the light shielding film 30 was 24 nm.

Another transparent substrate was prepared, which has a light shielding film formed on its main surface under the same conditions as above without the other films, and which was subjected to heat treatment. The sheet resistance of the light shielding film of Comparative Example 1 was measured, resulting in 168 kΩ/Square, which was significantly above 1.0 kΩ/Square. Further, the refractive index n and extinction coefficient k of the light shielding film to the light of 400 nm to 700 nm wavelength were measured using a spectroscopic ellipsometer. As a result, the extinction coefficient k to the light of 400 nm wavelength was 1.23, the extinction coefficient k to the light of 550 nm wavelength was 1.27, and the extinction coefficient k to the light of 700 nm wavelength was 1.2, and the values were below 2.0. The refractive index n to the light of 400 nm wavelength was 2.42, the refractive index n to the light of 550 nm wavelength was 2.64, and refractive index n to the light of 700 nm wavelength was 2.67.

Further, the light shielding film was analyzed by an X-ray photoelectron spectroscopy (XPS; with RBS corrections). As a result, it was confirmed that the region near the surface that is opposite to the transparent substrate side of the light shielding film (region up to about 2 nm depth from the surface) has a composition gradient portion having more oxygen content (40atom % or more oxygen content) than other regions. Further, the content of each constituent element in the region of the light shielding film excluding the composition gradient portion was found to be, at an average value, Cr:56atom %, O:29atom %, and C:15atom %. Moreover, it was confirmed that the difference of each constituent element in the thickness direction of the region of the light shielding film excluding the composition gradient portion was 3atom % or less in all cases, and there was substantially no composition gradient in the thickness direction.

Since it was difficult to visually identify the boundary between the region where the main surface is exposed and the region where the light shielding film was formed in the light shielding film of Comparative Example 1, it was difficult to finely adjust the position to dispose the masking plate with high precision. Therefore, it is difficult to securely avoid formation of the light shielding film wrapping around the side surface and the chamfered surface.

### [Manufacture of Phase Shift Mask]

Next, using the mask blank of Comparative Example 1, a plurality of phase shift masks of Comparative Example 1 was manufactured by the procedure similar to that of Example 1.

On the manufactured phase shift mask of Comparative Example 1, a simulation of a transfer image was made using AIMS193 (manufactured by Carl Zeiss) assuming that an exposure transfer was made on a resist film on a semiconductor device at an exposure light of 193 nm wavelength, similarly to Example 1. The exposure transfer image of this simulation was verified, and a transfer defect was confirmed in some phase shift masks. The transfer defect is assumed as caused by failure to write a correct pattern due to charge up of the resist and by generation of dust resulted from adhesion of the light shielding film to the chamfered surface of the substrate. From this result, it can be considered that when the phase shift mask of Comparative Example 1 was set on a mask stage of an exposure apparatus and a resist film on a semiconductor device was transferred by exposure, a defected area will generate on a circuit pattern to be finally formed on the semiconductor device.

### DESCRIPTION OF REFERENCE NUMERALS

10. transparent substrate
11 (11a, 11b). main surface
12. side surface
13. chamfered surface
14. inner region
15. outer peripheral region
16. ground pin grounding location
17. center
20. phase shift film
20a. phase shift pattern
30. light shielding film
30a, 30b. light shielding pattern
31. hard mask film
31a. hard mask pattern
40a, 40b. resist pattern
50. sputtering target
51. substrate retaining portion
52. shielding plate
100. mask blank
200. phase shift mask

1. A mask blank comprising a substrate and a thin film,
wherein the substrate comprises two main surfaces and a side surface with a chamfered surface provided between the two main surfaces and the side surface;
wherein one main surface of the two main surfaces comprises an inner region including a center of the main surface and an outer peripheral region outside of the inner region;
wherein the thin film is provided on the inner region of the main surface;
wherein a surface reflectance Rs of the outer peripheral region of the main surface with respect to light of 400 nm to 700 nm wavelength is 10% or less; and
provided that Rf is a surface reflectance with respect to light of 400 nm to 700 nm wavelength in one section among sections of the thin film in the range of 9 nm to 10 nm film thickness, a contrast ratio (Rf/Rs) is 3.0 or more.

2. The mask blank according to claim 1, wherein a surface reflectance of the one section with respect to the light of 400 nm to 700 nm wavelength is 20% or more.

3. The mask blank according to claim 1 wherein, provided that RfB is a surface reflectance with respect to light of 400 nm wavelength at the one section, that RfG is a surface reflectance to light of 550 nm wavelength at the one section, and that RfR is a surface reflectance to light of 700 nm wavelength at the one section, a standard deviation calculated between the three surface reflectances RfB, RfG, and RfR is 1.0 or less.

4. The mask blank according to claim 1, wherein the thin film has an extinction coefficient k of 1.5 or more with respect to the light of 400 nm to 700 nm wavelength.

5. The mask blank according to claim 1, wherein an average film thickness of the thin film is greater than 10 nm and 60 nm or less.

6. The mask blank according to claim 1, wherein an intermediate film is provided between the one main surface and the thin film in an interior region from an outer edge of the inner region to a center of the one main surface.

7. The mask blank according to claim 6, wherein the intermediate film is a light-semitransmissive film that transmits exposure light of an ArF excimer laser with a transmittance of 1% or more.

8. A transfer mask provided with a transfer pattern in the thin film of the mask blank according to claim 1.

9. A transfer mask comprising a transfer pattern in the intermediate film of the mask blank of claim 6, and comprising a pattern including a light shielding band in the thin film.

10. A method of manufacturing a semiconductor device comprising transferring a transfer pattern to a resist film on a semiconductor substrate by exposure using the transfer mask according to claim 8.

11. A method of manufacturing a semiconductor device comprising transferring a transfer pattern to a resist film on a semiconductor substrate by exposure using the transfer mask according to claim 9.

12. The mask blank according to claim 2 wherein, provided that RfB is a surface reflectance with respect to light of 400 nm wavelength at the one section, that RfG is a surface reflectance to light of 550 nm wavelength at the one section, and that RfR is a surface reflectance to light of 700 nm wavelength at the one section, a standard deviation calculated between the three surface reflectances RfB, RfG, and RfR is 1.0 or less.

13. The mask blank according to claim 12, wherein the thin film has an extinction coefficient k of 1.5 or more with respect to the light of 400 nm to 700 nm wavelength.

14. The mask blank according to claim 13, wherein an average film thickness of the thin film is greater than 10 nm and 60 nm or less.

15. The mask blank according to claim 14, wherein an intermediate film is provided between the one main surface and the thin film in an interior region from an outer edge of the inner region to a center of the one main surface.

16. The mask blank according to claim 15, wherein the intermediate film is a light-semitransmissive film that transmits exposure light of an ArF excimer laser with a transmittance of 1% or more.

17. A transfer mask provided with a transfer pattern in the thin film of the mask blank according to claim 15.

18. A transfer mask comprising a transfer pattern in the intermediate film of the mask blank of claim 16 comprising a pattern including a light shielding band in the thin film.

19. A method of manufacturing a semiconductor device comprising transferring a transfer pattern to a resist film on a semiconductor substrate by exposure using the transfer mask according to claim 18.
